(19) United States
(12) Patent Application Publication
(10) Pub. No.: US 2010/0126559 A1
(43) Pub. Date: May 27, 2010

(54) Semi-Transparent Thin-Film Photovoltaic Modules and Methods of Manufacture

(75) Inventors: Kevin Laughton Cunningham, Mountain View, CA (US); Tzay-Fa Su, San Jose, CA (US)

Correspondence Address: DIEHL SERVILLA LLC, 77 BRANT AVENUE, SUITE 210, CLARK, NJ, 07066, US

(73) Assignee: Applied Materials, Inc., Santa Clara, CA (US)

(21) Appl. No.: 12/324,213

(22) Filed: Nov. 26, 2008

(51) Int. Cl. H01L 31/048; H01L 31/042; H01L 31/18

(52) U.S. Cl. 136/251; 136/244; 438/73; 257/E31.126

(57) ABSTRACT

Semi-transparent thin-film photovoltaic modules and methods of making the same are described. A thin-film photovoltaic module comprises a transparent conductive oxide layer, a photoabsorptive layer and a reflective back contact layer. A series of scribes is created between application of each layer with some scribes rendering transparent portions of the final module.

### BACKGROUND

Embodiments of the present invention generally relate to photovoltaic cells and methods for making photovoltaic cells. Specific embodiments pertain to semi-transparent photovoltaic cells and methods of making semi-transparent photovoltaic cells.

Kiyama et al. U.S. Pat. No. 4,650,524 describes a laser scribing technique for producing thin-film solar circuits. The technique produces a small transparent strip between each cell, and is now known as Pattern 3 scribe. A typical Pattern 3 scribe manufacturing process for solar cells is shown in FIGS. 1A through 1G. Starting at FIG. 1A, solar cells are manufactured by starting with a glass sheet or substrate 101. An exemplary thickness for the glass sheet is about 3 mm. In the art, this glass substrate is typically called a glass superstrate because sunlight will enter through this support glass. During the manufacture of a solar cell, shown in FIG. 1B, a continuous, uniform layer of a transparent conductive oxide (TCO) 102 is deposited on the glass substrate 101. The thickness of the TCO layer 102 is typically up to about a few thousand nanometers. The TCO layer 102 eventually forms the front electrodes of the solar cell. Suitable materials for the TCO layer 102 include, but are not limited to, aluminum-doped zinc oxide (AZO), boron-doped zinc oxide, fluorine-doped tin oxide, indium tin oxide (ITO), indium molybdenum oxide (IMO), indium zinc oxide (IZO) and tantalum oxide. The TCO layer 102 can be deposited by any suitable process, such as chemical vapor deposition (CVD) or physical vapor deposition (PVD).

In FIG. 1C, after the deposition of the TCO layer 102, a laser scribing process, which is often referred to as pattern 1 or P1, scribes strips 104 through the entire thickness of the TCO layer 102. The scribed strips are usually 5-20 mm apart. After the scribing process P1, a photoabsorptive layer 106 (frequently p-type, n-type or intrinsic silicon) is deposited over the TCO layer 102, as shown in FIG. 1D. The total thickness of the photoabsorptive layer 106 is typically on the order of 0.25-3 μm, and this layer is usually deposited by chemical vapor deposition or other suitable processes. The photoabsorbtive layer can be made of amorphous silicon, crystalline silicon, a combination of amorphous and crystalline silicon (so called tandem cell), or other materials like copper indium gallium selenide (CIGS), cadmium telluride, copper indium selenide (CIS), organic dyes and others.

Referring to FIG. 1E, the photoabsorptive deposition is followed by a second laser scribing, often referred to as pattern 2 or P2, which completely cuts strips 108 through the photoabsorptive layer 106. As shown in FIG. 1F, a back contact layer 110 that forms the rear electrode is deposited over the photoabsorptive layer 106. This back contact layer 110 will contain a number of materials which could include, but are not limited to, aluminum-doped zinc oxide (AZO), boron-doped zinc oxide, aluminum, silver, nickel, and vanadium. The back contact layer 110 can be deposited by any suitable deposition process, such as physical vapor deposition (PVD). Referring now to FIG. 1G, a third scribing process, called Pattern 3 or P3, is used to scribe strips 112 through the back contact layer 110 and the photoabsorptive layer 106. The panel is then typically sealed with a rear surface glass lamination (not shown). The area between, and including, the P1 and P3 scribes results in a “dead zone” 114 which is inactive for photoconversion. If this dead zone is widened for any reason, it will decreases the overall efficiency of the cell. The dead zone is typically in the range of about 100 μm to about 500 μm, depending on the accuracy of the lasers and optics employed in the scribing processes. The third scribe (P3) provides isolation of the reflective back contact layer by scribing away the absorber and back contact layers. This exposes the front TCO allowing light to pass through this scribe. There are no additional opaque layers deposited in the manufacturing process, so this transparent feature remains a permanent part of the thin-film solar module.

A typical photovoltaic cell pitch, or spacing between each scribe is about 10 mm. When a photocurrent is generated in the photoabsorptive layer 106 of one cell, the current flows to the reflective back contact layer 110, over the location of the P1 scribe 104, through the P2 scribe 108 to the front TCO layer 102 of the adjacent cell, under the location of the P3 scribe 112, and to the photoabsorptive layer 106 of the next cell. The P1 scribe 104 prevents current flow directly across to adjacent front TCO layer 102, and, similarly, the P3 scribe 112 prevents current flow directly across to reflective back contact layer 110 on the adjacent cell. The front TCO 102 does not have very good conductivity, so significant front TCO resistivity loss takes place. If P3 112 is far from P2 108 or if P3 112 is very wide, this front TCO 102 resistivity loss will be greater.

FIG. 2 shows a photovoltaic cell 100 made according the method illustrated in FIGS. 1A through 1G. The photovoltaic cell 100 shows scribe strips 104, 108, 112. These thin-film panels are almost entirely opaque with the typical distance between P1 104 and P3 112 being about 100 μm. However, these thin-films are typically deposited on large sheets of glass. These glass substrates are similar in size to architectural glass. Architects would like to use thin-film solar panels in their designs but the use of opaque panels is limited. A semi-transparent solar panel could be used in architectural designs, allowing some light to pass through the panels while some light is converted into energy.

Therefore, there is a need to provide semi-transparent thin-film solar cells and methods for making semi-transparent thin-film solar cells.

### SUMMARY

According to one or more embodiment of the invention, the P3 scribe is widened. For example, to create 10% transparency with a panel that has a 10 mm scribe pitch, P3 would be 1 mm wide. Of course, a finer pitch could be selected. For example, the pitch could be 5 mm, and the P3 width would be 0.5 mm. The finer the pitch, the less obvious the lines will be. However, a finer pitch will require more P1 and P2 scribe lines which means more time in P1 and P2 laser scribing systems. More scribe lines will lead to more area lost on the panel to scribing. The loss of area to the wide P3 is intentional, but the front TCO resistivity loss will increase with a wider P3.

In other aspects the P3 lines are not straight but patterned or serrated. It may be advantageous to have the edge of P3 closest to P2 straight and the other side serrated. This has several benefits: a more pleasing appearance is produced, and the effective distance in which the current flow is constrained under the P3 region is reduced. Other aspects have the serrations shaped to allow most of the current flowing from cell to cell to follow a very short path.

Further embodiments of the invention are directed to semi-transparent photovoltaic modules where an additional scribe is made in the gap between P1 and P2, removing the absorber and back contact. In modules of these embodiments, current flows through the high conductivity back contact in this region of the circuit. As a result, there would be little change in the circuit resistivity loss. The holes can be any shape as long as there are a number of connections between the back contact above the absorber. If a scribe pitch of 10 mm was used, and a transparency of 9% was desired, the P1 and P2 lines could be separated by ˜1.2 mm and a region 1 mm wide scribed with 0.1 mm breaks in the scribing every 1 mm along the length of the scribe.

One or more embodiments of the present invention relate to semi-transparent thin-film photovoltaic modules. The modules comprise a superstrate having a front side and a back side and a plurality of photovoltaic cells having a width connected in series. Each photovoltaic cells comprises a transparent conductive oxide layer on the back side of the superstrate. The layer has a first scribe through the layer exposing the superstrate. A light absorbing layer overlies the transparent conductive oxide layer. The light absorbing layer has a second scribe adjacent to and substantially parallel to the first scribe. The second scribe exposes the transparent conductive oxide layer through the light absorbing layer. A back contact layer overlies the light absorbing layer. The back contact layer and the light absorbing layer have a third scribe, adjacent to and substantially parallel to the second scribe, and opposite the first scribe. The third scribe is at least about 5% of the width of the photovoltaic cell and exposes the underlying transparent conductive oxide layer through the light absorbing layer and the back contact layer.

Other embodiments relate to semi-transparent thin-film photovoltaic modules comprising a superstrate having a front side and a back side and a plurality of photovoltaic cells connected in series. The photovoltaic cells comprise a transparent conductive oxide layer on the back side of the superstrate. The layer has a first scribe through the layer exposing the superstrate. A light absorbing layer overlies the transparent conductive oxide layer. The light absorbing layer has a second scribe adjacent to and substantially parallel to the first scribe. The second scribe exposes the transparent conductive oxide layer through the light absorbing layer. A back contact layer overlies the light absorbing layer. The back contact layer and the light absorbing layer have a third scribe forming a serrated pattern. The third scribe being adjacent to the second scribe and opposite the first scribe. The third scribe exposes the underlying transparent conductive oxide layer through the light absorbing layer and the back contact layer.

Further embodiments are directed to semi-transparent thin-film photovoltaic modules comprising a superstrate having a front side and a back side and a plurality of photovoltaic cells connected in series. The photovoltaic cells comprise a transparent conductive oxide layer on the back side of the superstrate. The layer has a first scribe through the layer exposing the superstrate. A light absorbing layer overlies the transparent conductive oxide layer, the light absorbing layer has a second scribe adjacent to and substantially parallel to the first scribe. The second scribe exposes the transparent conductive oxide layer through the light absorbing layer. A back contact layer overlies the light absorbing layer. The back contact layer and the light absorbing layer have a third scribe adjacent to, and substantially parallel to, the second scribe, and opposite the first scribe. The third scribe exposes the underlying transparent conductive oxide layer through the light absorbing layer and the back contact layer. A fourth scribe between the first and second scribes. The fourth scribe exposes the underlying transparent conductive oxide layer through the light absorbing layer and the back contact layer.

Additional embodiments are directed to methods of making photovoltaic cells. A transparent conductive oxide layer is applied to a superstrate. A portion of the transparent conductive oxide layer is removed with a first scribe process to provide a first scribe. A light absorbing, or photoabsorptive layer, is applied to the scribed transparent conductive oxide layer. A portion of the photoabsorptive layer is removed to expose the transparent conductive oxide layer with a second scribe process to provide a second scribe. The second scribe being substantially parallel to the first scribe. A back contact layer is applied to the scribed photoabsorptive layer. A portion of the back contact layer and the photoabsorptive layer are removed to expose the conductive oxide layer with a third scribe process to provide a third scribe. The third scribe being substantially parallel to the second scribe and opposed to the first scribe. Additional area of the back contact layer and the photoabsorptive layer is removed, exposing additional area of the transparent conducive oxide layer.

The foregoing has outlined rather broadly certain features and technical advantages of the present invention. It should be appreciated by those skilled in the art that the specific embodiments disclosed may be readily utilized as a basis for modifying or designing other structures or processes within the scope present invention. It should also be realized by those skilled in the art that such equivalent constructions do not depart from the spirit and scope of the invention as set forth in the appended claims.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1G shows stages in the making of photovoltaic cells using a laser scribing technique according to the prior art;

FIG. 2 shows a photovoltaic cell resulting from the prior art stages of FIGS. 1A-1G;

FIGS. 3A and 3B show a photovoltaic cell according to one or more embodiments of the invention;

FIG. 4, shows a photovoltaic cell according to one or more embodiments of the invention;

FIG. 5 shows a photovoltaic cell according to one or more embodiments of the invention;

FIG. 6 shows a photovoltaic cell according to one or more embodiments of the invention; and

FIGS. 7A and 7B show photovoltaic cells according to one or more embodiments of the invention.

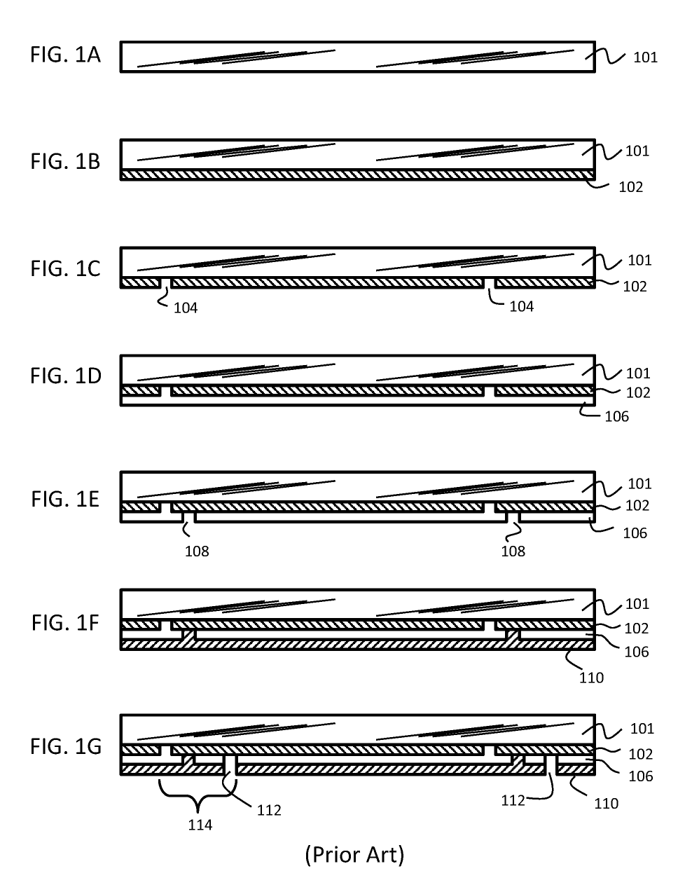

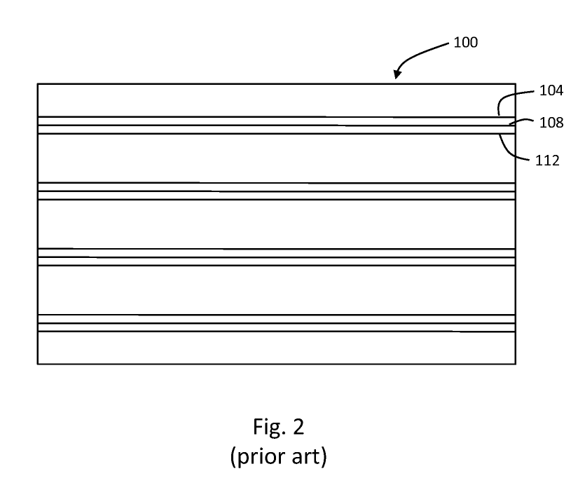

### DETAILED DESCRIPTION

Before describing several exemplary embodiments of the invention, it is to be understood that the invention is not limited to the details of construction or process set forth in the following description. The invention is capable of other embodiments and of being practiced or being carried out in various ways.

As used in this specification and the appended claims, the singular forms “a”, “an” and “the” include plural referents unless the context clearly indicates otherwise. For example, reference to a “cell” may also refer to more than one cell, and the like.

As used in this specification and the appended claims, the terms “scribe” and “scribing” refers to any method suitable for the removal of deposited layers. For example, scribing can be accomplished by laser scribing, photolithography, wet etching, or combinations of techniques. Use of the terms “scribe” and “scribing” should not be read as limiting the invention to any particular suitable technique.

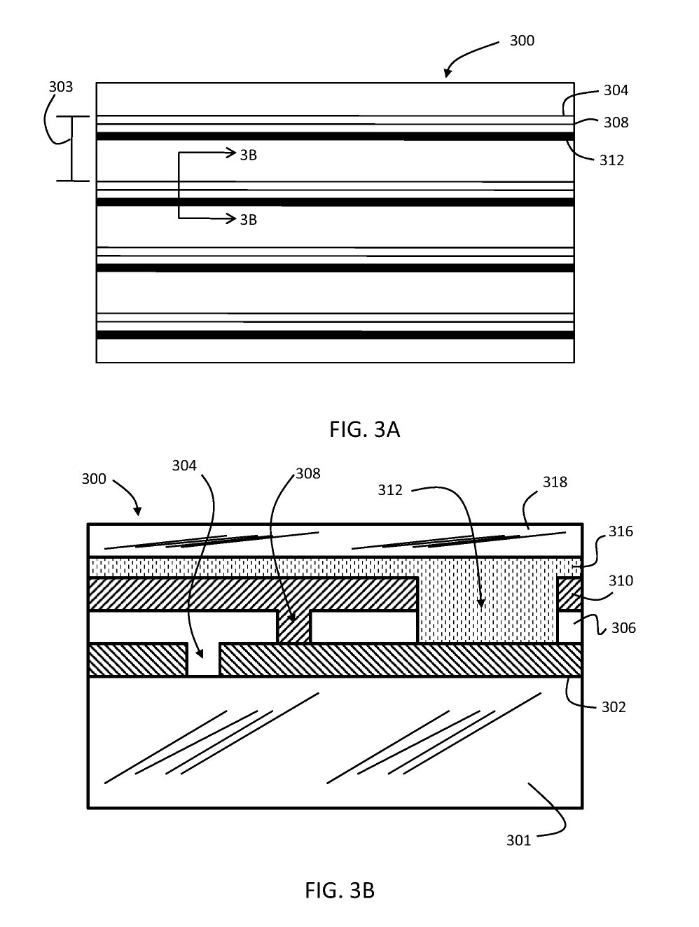

One or more embodiments of the invention are directed to semi-transparent thin-film photovoltaic modules 300. FIG. 3A shows a photovoltaic module 300 having a plurality of photovoltaic cells 303. A side view along line 3B is shown in FIG. 3B where the individual layers and scribes are shown.

A superstrate 301 has a plurality of photovoltaic cells 303 which are connected in series. Each photovoltaic cell 303 has a transparent conductive oxide layer 302 on the back side of the superstrate 301. The TCO layer 302 has a first scribe 304 which exposes the superstrate 301. A light absorbing layer 306, or photoabsorptive layer, overlies the transparent conductive oxide layer 302. The light absorbing layer 306 has a second scribe 308 adjacent to, and substantially parallel to, the first scribe 304. The second scribe 308 exposes the transparent conductive oxide layer 302 through the light absorbing layer 306. A back contact layer 310 overlies the light absorbing layer 306. The back contact layer 310 and the light absorbing layer 306 have a third scribe 312 adjacent to, and substantially parallel to, the second scribe 308 and opposite the first scribe 304. The third scribe 312 is at least about 5% of the width of the photovoltaic cell 303 and exposes the underlying transparent conductive oxide layer 302 through the light absorbing layer 306 and the back contact layer 310.

The width of the third scribe 312 may be varied according to the desired transparency of the resultant photovoltaic module 300. For example, the third scribe 312 of some aspects is at least about 10% of the total width of the photovoltaic cell 303.

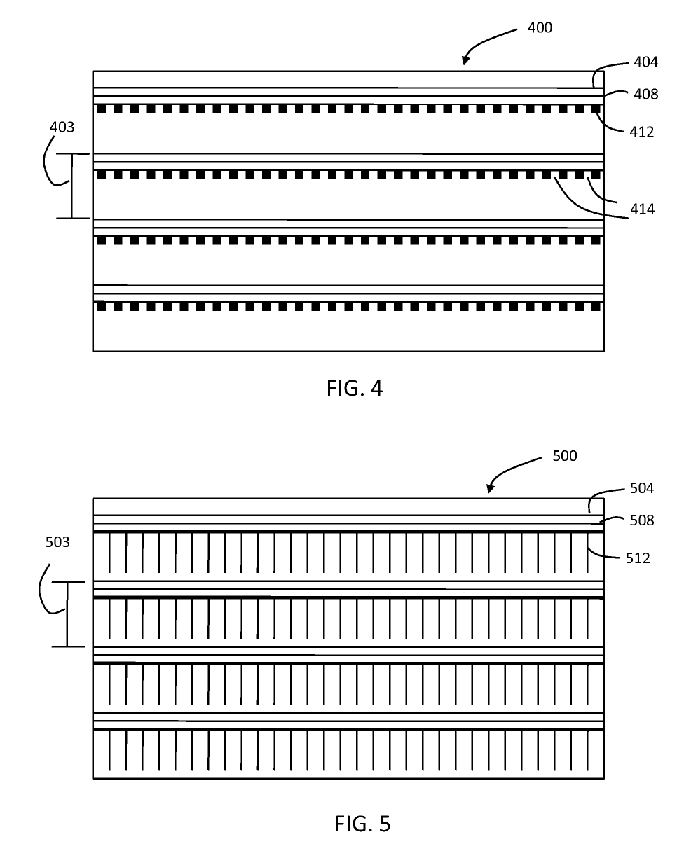

FIGS. 4-6 shows semi-transparent thin-film photovoltaic modules 400, 500, 600 according to various embodiments of the invention. A superstrate having a front side and a back side has a plurality of photovoltaic cells 403, 503, 603 connected in series. Each photovoltaic cell 403, 503, 603 comprises a transparent conductive oxide layer on the back side of the superstrate. The TCO layer has a first scribe 404, 504, 604 through the layer exposing the superstrate. A light absorbing layer overlies the transparent conductive oxide layer. The light absorbing layer has a second scribe 408, 508, 608 adjacent to and substantially parallel to the first scribe 404. The second scribe 408, 508, 608 exposes the transparent conductive oxide layer through the light absorbing layer. A back contact layer overlies the light absorbing layer. The metal layer and light absorbing layer have a third scribe 412, 512, 612 forming a serrated pattern. The third scribe 412, 512, 612 is adjacent to the second scribe 408, 508, 608 and opposite the first scribe 404, 504, 604. The third scribe 412, 512, 612 exposes the underlying transparent conductive oxide layer through the light absorbing layer and the back contact layer.

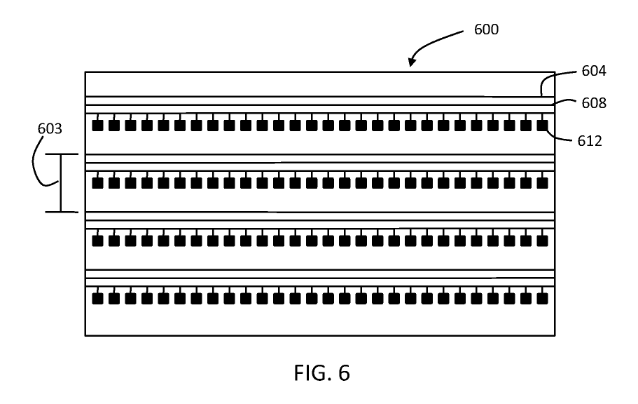

FIG. 4 shows an aspect of the invention where the third scribe 412 is shown as having a serrated pattern including a plurality of teeth or notches 414. The teeth or notches shown are not limited to any particular shape or pattern. In FIG. 5, the third scribe 512 is shown with scribe lines extending perpendicularly. FIG. 6 shows the third scribe 612 as a combination of serrations and perpendicularly extending lines. The patterns shown are intended to be exemplary of embodiments of the invention and should not be taken as limiting the scope of the invention.

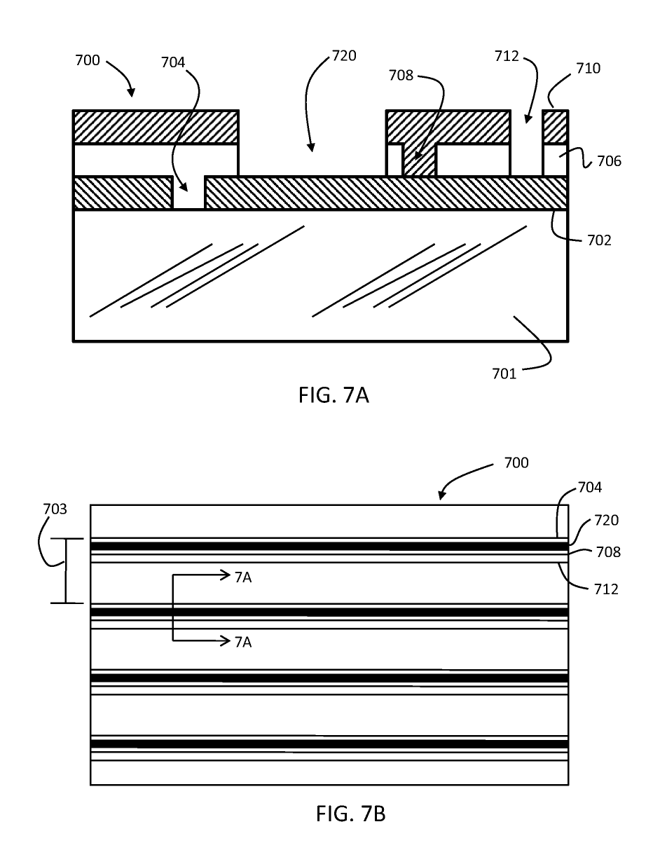

FIG. 7A shows a side view of a semi-transparent thin-film photovoltaic module 700 according to other embodiments of the invention. A front view of the photovoltaic module 700 having a plurality of photovoltaic cells 703 is shown in FIG. 7B. A superstrate 701 having a front side and a back side has a plurality of photovoltaic cells thereon connected in series. Each photovoltaic cell has a transparent conductive oxide layer 702 on the back side of the superstrate 701. The TCO layer 702 has a first scribe 704 through the TCO layer 702 exposing the superstrate 701. A light absorbing layer 706, or photoabsorptive layer, overlies the transparent conductive oxide layer 702. The light absorbing layer 706 has a second scribe 708 adjacent to and substantially parallel to the first scribe 704. The second scribe 708 exposing the transparent conductive oxide layer 702 through the light absorbing layer 706. A back contact layer 710 overlies the light absorbing layer 706. The back contact layer 710 and light absorbing layer 706 have a third scribe 712 adjacent to and substantially parallel to the second scribe 708 and opposite the first scribe 704. The third scribe 712 exposes the underlying transparent conductive oxide layer 702 through the light absorbing layer 706 and the back contact layer 710. A fourth scribe 720 is between the first scribe 704 and second scribe 708. The fourth scribe 720 exposes the underlying transparent conductive oxide layer 702 through the light absorbing layer 706 and the back contact layer 710.

In some aspects of the invention, the photovoltaic module has a fourth scribe 720 comprising a series of closely spaced dots. In other aspects, the fourth scribe 720 can be any other suitable pattern, including, but not limited to, dots, squares, solid lines, dashed lines and wavy lines.

The photovoltaic modules of various aspects, as shown in FIG. 3, may further comprise a polymer laminate layer 316 on the back contact layer 310 and a glass layer 318 on the polymer laminate layer. The glass layer 318 may also be plastic or other suitable backer material.

The width of the photovoltaic cells according to various aspects of the invention may be in the range of about 5 mm and about 20 mm. The width in specific embodiments may be in the range of about 5 mm and about 10 mm. In other aspects, the photovoltaic cells may be greater than 10 mm wide. In further aspects, the photovoltaic cells are greater than about 2 mm wide.

The width of the photovoltaic modules and scribe lines may be adjusted to allow light to be transmitted through the module. In certain embodiments, the photovoltaic modules transmit in the range of about 5% and about 50% of the incident light. In detailed embodiments, modules transmit between about 5% and about 20% of the incident light. Specific aspects of the invention include photovoltaic modules which are operative to transmit about 10% of incident light. In other detailed aspects, the modules are operative to transmit at least about 10% of the incident light. In further detailed aspects, the modules are operative to transmit at least about 20% of the incident light.

Where more than three total scribes are employed, the combined area of the third scribe and the fourth scribe in some detailed aspects is at least about 10% of the area of the photovoltaic cell. In other detailed aspects, the combined area of the third scribe and any subsequent scribes is at least about 10% of the area of the photovoltaic cell. In further specific aspects, the combined area of all scribes through the back contact layer and the absorbing layer is greater than at least about 15% of the area of the photovoltaic cell.

Further embodiments of the invention are directed to methods of making semi-transparent photovoltaic cells. A transparent conductive oxide layer is applied to a superstrate. A portion of the transparent conductive oxide layer is removed with a first scribe process providing a first scribe. A photoabsorptive layer is applied to the scribed transparent conductive oxide layer. A portion of the photoabsorptive layer is removed with a second scribe process, providing a second scribe, to expose the transparent conductive oxide layer. The second scribe is substantially parallel to the first scribe. A back contact layer is applied to the scribed photoabsorptive layer. A portion of the back contact layer and the photoabsorptive layer is removed with a third scribe process, providing a third scribe. The third scribe process exposes the transparent conductive oxide layer and is substantially parallel to the second scribe and opposed to the first scribe. Additional area of the back contact layer and the photoabsorptive layer is removed, exposing additional area of the transparent conductive oxide layer. In some detailed aspects of the invention, a polymer layer and a glass layer may be applied over the scribed back contact layer.

In some specific aspects, the additional area of the back contact layer and the photoabsorptive layer is removed during the third scribe process and at least about 5% of the back contact layer and the photoabsorptive layer are removed. In other detailed aspects, the additional area of the back contact layer and photoabsorptive layer removed results in the third scribe having a serrated profile.

In further detailed aspects, the additional area of the back contact layer and photoabsorptive layer removed is substantially perpendicular to the at least one third scribe. In various detailed aspects, the additional area of the back contact layer and photoabsorptive layer is removed during a fourth scribe process and is substantially parallel to and between the at least one first scribe and the at least one second scribe.

Reference throughout this specification to “one embodiment,” “certain embodiments,” “one or more embodiments,” “an embodiment,” “one aspect,” “certain aspects,” “one or more embodiments” and “an aspect” means that a particular feature, structure, material, or characteristic described in connection with the embodiment is included in at least one embodiment of the invention. Thus, the appearances of the phrases such as “in one or more embodiments,” “in certain embodiments,” “in one embodiment,” “in an embodiment,” “according to one or more aspects,” “in an aspect,” etc., in various places throughout this specification are not necessarily referring to the same embodiment or aspect of the invention. Furthermore, the particular features, structures, materials, or characteristics may be combined in any suitable manner in one or more embodiments or aspects. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

1. A semi-transparent thin-film photovoltaic module comprising:
a superstrate having a front side and a back side;
a plurality of photovoltaic cells having a width connected in series, each photovoltaic cells comprising:
a transparent conductive oxide layer on the back side of the superstrate, the layer having a first scribe through the layer exposing the superstrate;
a light absorbing layer overlying the transparent conductive oxide layer, the light absorbing layer having a second scribe adjacent to and substantially parallel to the first scribe, the second scribe exposing the transparent conductive oxide layer through the light absorbing layer; and
a back contact layer overlying the light absorbing layer, the back contact layer and light absorbing layer having a third scribe adjacent to and substantially parallel to the second scribe and opposite the first scribe, the third scribe being at least about 5% of the width of the photovoltaic cell and exposing the underlying transparent conductive oxide layer through the light absorbing layer and the back contact layer.

2. The photovoltaic module of claim 1, wherein the third scribe is in the range of about 5% and about 50%_of the total width of the photovoltaic cell.

3. The photovoltaic module of claim 1, further comprising a polymer laminate on the back contact layer and glass on the polymer laminate layer.

4. The photovoltaic module of claim 1, wherein each individual photovoltaic cell is about 5 mm to about 20 mm in width.

5. The photovoltaic module of claim 1, wherein the photovoltaic module is operative to transmit in the range of about 5% and about 50% of incident light.

6. The photovoltaic module of claim 1, wherein the photovoltaic module is operative to transmit in the range of about 5% and about 20% of incident light.

7. The photovoltaic module of claim 1, wherein the absorber is one or more of silicon, cadmium telluride, copper indium gallium selenide, and copper indium selenide.

8. The photovoltaic module of claim 1, wherein
the third scribe forms a serrated pattern.

9. (canceled)

10. The photovoltaic module of claim 1, wherein the third scribe removes at least about 10% of the back contact layer.

11. (canceled)

12. (canceled)

13. (canceled)

14. (canceled)

15. A semi-transparent thin-film photovoltaic module comprising:
a superstrate having a front side and a back side;
a plurality of photovoltaic cells connected in series, the photovoltaic cells comprising:
a transparent conductive oxide layer on the back side of the superstrate, the layer having a first scribe through the layer exposing the superstrate;
a light absorbing layer overlying the transparent conductive oxide layer, the light absorbing layer having a second scribe adjacent to and substantially parallel to the first scribe, the second scribe exposing the transparent conductive oxide layer through the light absorbing layer;
a back contact layer overlying the light absorbing layer, the back contact layer and light absorbing layer having a third scribe adjacent to and substantially parallel to the second scribe and opposite the first scribe the third scribe exposing the underlying transparent conductive oxide layer through the light absorbing layer and the back contact layer; and
a fourth scribe between the first and second scribes, the fourth scribe exposing the underlying transparent conductive oxide layer through the light absorbing layer and the back contact layer.

16. The photovoltaic module of claim 15, wherein the combined area of the third scribe and the fourth scribe is at least about 10% of the area of the photovoltaic cell.

17. The photovoltaic module of claim 15, further comprising a polymer laminate on the back contact layer and glass on the polymer laminate layer.

18. The photovoltaic module of claim 15, wherein individual photovoltaic cells are in the range of about 5 mm and about 20 mm wide.

19. The photovoltaic module of claim 15, wherein the module is operative to transmit in the range of about 5% and about 50% of incident light.

20. The photovoltaic module of claim 15, wherein the fourth scribe comprises a series of closely spaced dots.

21. A method of making a photovoltaic cell comprising:
applying a transparent conductive oxide layer to a superstate;
removing a portion of the transparent conductive oxide layer with a first scribe process to provide a first scribe;
applying a photoabsorptive layer to the scribed transparent conductive oxide layer;
removing a portion of the photoabsorptive layer to expose the transparent conductive oxide layer with a second scribe process to provide a second scribe substantially parallel to the first scribe;
applying a back contact layer to the scribed photoabsorptive layer;
removing a portion of the back contact layer and photoabsorptive layer to expose the conductive oxide layer with a third scribe process to provide a third scribe substantially parallel to the second scribe and opposed to the first scribe; and
removing additional area of the back contact layer and photoabsorptive layer, exposing additional area of the transparent conductive oxide layer.

22. The method of claim 21, wherein removing additional area of the back contact layer and the photoabsorptive layer occurs during the third scribe process and at least about 5% of the back contact layer and the photoabsorptive layer is removed.

23. The method of claim 21, wherein removing additional area of the back contact layer and photoabsorptive layer results in the third scribe having a serrated profile.

24. The method of making a photovoltaic cell according to claim 21, wherein the additional area of the back contact layer and photoabsorptive layer removed is substantially perpendicular to the at least one third scribe.

25. The method of making a photovoltaic cell according to claim 21, wherein removing additional area of the back contact layer and photoabsorptive layer occurs during a fourth scribe process and is substantially parallel to and between the at least one first scribe and the at least one second scribe.
